(19) United States
(12) Patent Application Publication
(10) Pub. No.: US 2025/0204048 A1
(43) Pub. Date: Jun. 19, 2025

(54) SELF-ALIGNED BACKSIDE CHANNEL REMOVAL

(71) Applicant: INTERNATIONAL BUSINESS MACHINES CORPORATION, ARMONK, NY (US)

(72) Inventors: Reinaldo Vega, Mahopac, NY (US); Ruilong Xie, Niskayuna, NY (US); James P. Mazza, Saratoga Springs, NY (US); Takashi Ando, Eastchester, NY (US); Nicholas Anthony Lanzillo, Wynantskill, NY (US); David Wolpert, Poughkeepsie, NY (US)

(21) Appl. No.: 18/544,501

(22) Filed: Dec. 19, 2023

(51) Int. Cl. H01L 27/12

(52) U.S. Cl. CPC H10D 86/60; H10D 86/0214; H10D 86/0221; H10D 86/451; H10D 86/441

(57) ABSTRACT

A semiconductor structure including a first stack of semiconducting layers, a second stack of semiconducting layers, wherein the first stack of semiconducting layers has at least one fewer layer than the second stack of semiconducting layers, and a backside channel plug directly beneath the first stack of semiconducting layers.

### BACKGROUND

The present invention generally relates to semiconductor structures, and more particularly to transistor structures having stacks of semiconducting layers with different number of channels.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet FET includes a plurality of stacked nanosheets extending between a pair of source/drain epitaxial regions. The device may be a gate-all-around device or transistor in which the gate surrounds a portion of the nanosheet channel. A nanosheet device contains one or more layers of semiconductor channel material portions having a vertical thickness that is substantially less than its width.

### SUMMARY

According to an embodiment of the present invention, a semiconductor structure is provided. The semiconductor structure may include a first stack of semiconducting layers, a second stack of semiconducting layers, wherein the first stack of semiconducting layers has at least one fewer layer than the second stack of semiconducting layers, and a backside channel plug directly beneath the first stack of semiconducting layers.

According to another embodiment of the present invention, a semiconductor structure is provided. The semiconductor structure may include a first stack of semiconducting layers, a second stack of semiconducting layers, where a top surface of a top layer of the first stack of semiconducting layers is substantially flush with a top surface of a top layer of the second stack of semiconducting layers, and where a bottom surface of a bottom layer of the first stack of semiconducting layers is above a bottom surface of a bottom layer of the second stack of semiconducting layers, and a backside channel plug below the first stack of semiconducting layers.

According to another embodiment of the present invention, a semiconductor structure is provided. The semiconductor structure may include a first stack of semiconducting layers including a first gate surrounding at least one layer of the first stack of semiconducting layers, a second stack of semiconducting layers including a second gate surrounding at least one layer of the second stack of semiconducting layers, where a topmost surface of the first gate is substantially flush with a topmost surface of the second gate, and a bottommost surface of the first gate is above a bottommost surface of the second gate, and a backside channel plug below and in direct contact with the bottommost surface of the second gate.

### BRIEF DESCRIPTION OF THE DRAWINGS

The following detailed description, given by way of example and not intended to limit the invention solely thereto, will best be appreciated in conjunction with the accompanying drawings, in which:

FIG. 1, a top view of a generic structure is shown to provide spatial context to the different cross-sectional views and structural orientations of the semiconductor structures shown in the subsequent figures;

FIG. 2 is a cross-sectional view of the semiconductor structure during an intermediate step of a method of fabricating a transistor structure according to an exemplary embodiment;

FIG. 3 is a cross-sectional view of the semiconductor structure after flipping the assembly and recessing the substrate according to an exemplary embodiment;

FIG. 4 is a cross-sectional view of the semiconductor structure after removing and recessing remaining portions of the substrate according to an exemplary embodiment;

FIG. 5 is a cross-sectional view of the semiconductor structure after removing and recessing the placeholders to create backside recesses according to an exemplary embodiment;

FIG. 6 is a cross-sectional view of the semiconductor structure after forming protective caps within the backside recesses according to an exemplary embodiment;

FIG. 7 is a cross-sectional view of the semiconductor structure after forming a mask and forming backside access openings according to an exemplary embodiment;

FIG. 8 is a cross-sectional view of the semiconductor structure after removing portions of the gate and a bottommost channel region according to an exemplary embodiment;

FIG. 9 is a cross-sectional view of the semiconductor structure after removing remaining portions of the bottommost channel region according to an exemplary embodiment;

FIG. 10 is a cross-sectional view of the semiconductor structure after forming a backside channel plug according to an exemplary embodiment;

FIG. 11 is a cross-sectional view of the semiconductor structure after removing remaining portions of the substrate according to an exemplary embodiment;

FIG. 12 is a cross-sectional view of the semiconductor structure after forming a backside dielectric layer according to an exemplary embodiment;

FIG. 13 is a cross-sectional view of the semiconductor structure after forming backside contact trenches according to an exemplary embodiment;

FIG. 14 is a cross-sectional view of the semiconductor structure after removing the protective caps and the placeholders according to an exemplary embodiment;

FIGS. 15, 16, and 17 are cross-sectional views of the semiconductor structure after forming backside contact structures and backside wiring layers according to an exemplary embodiment;

FIG. 18 is a cross-sectional view of another semiconductor structure during an intermediate step of a method of fabricating a transistor structure according to an alternative exemplary embodiment;

FIG. 19 is a cross-sectional view of another semiconductor structure during an intermediate step of a method of fabricating a transistor structure according to an alternative exemplary embodiment;

FIG. 20 is a cross-sectional view of another semiconductor structure during an intermediate step of a method of fabricating a transistor structure according to an alternative exemplary embodiment;

FIG. 21 is a cross-sectional view of another semiconductor structure during an intermediate step of a method of fabricating a transistor structure according to an alternative exemplary embodiment;

FIG. 22 is a cross-sectional view of another semiconductor structure during an intermediate step of a method of fabricating a transistor structure according to an alternative exemplary embodiment; and

FIGS. 23, 24, and 25 are cross-sectional views of another semiconductor structure during an intermediate step of a method of fabricating a transistor structure according to an alternative exemplary embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Complementary field effect transistors, including gate-all-around transistor devices and nanosheet transistor devices, have known advantages over conventional transistor structures in terms of density, performance, power consumption, and integration. However, fabricating devices to suit different design constraints or requirements presents unique challenges. More specifically, for example, continued scaling of device dimensions to conserve power and optimize performance have known limitations.

For example, scaling RX width is a productive way to control or reduce power consumption; however, edge capacitance limits any benefit achieved by scaling RX width. Furthermore, setting aside any edge capacitance concerns, current lithography and patterning constraints limit RX width variations within a circuit row. Therefore, there is a need for other solutions to conserve power and optimize performance to suit different design constraints.

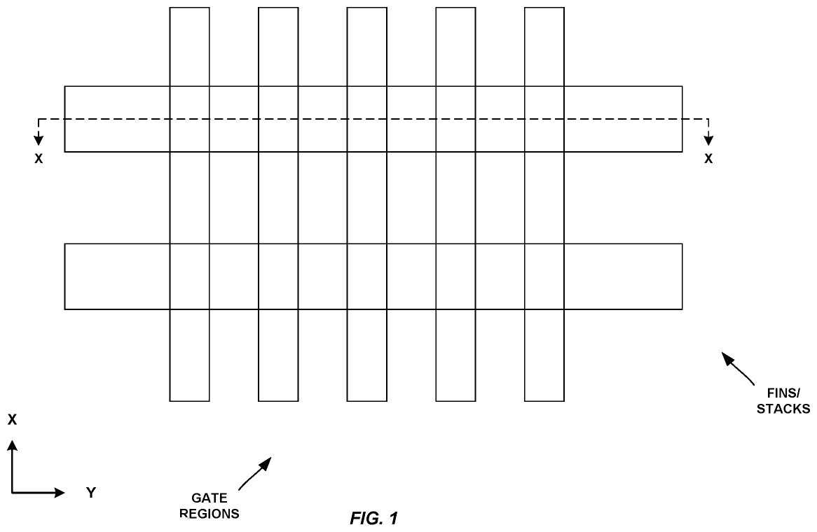

The present invention generally relates to semiconductor structures, and more particularly to transistor structures having stacks of semiconducting layers with different number of channels. More specifically, the transistor structures and associated method disclosed herein enable a novel solution for providing stacks of semiconducting layers having one or more channels removed. Exemplary embodiments of transistor structures having stacks of semiconducting layers with different number of channels are described in detail below by referring to the accompanying drawings in FIGS. 1 to 17. Those skilled in the art will readily appreciate that the detailed description given herein with respect to these figures is for explanatory purposes as the invention extends beyond these limited embodiments.

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

The generic structure illustrated in FIG. 1 shows multiple fins/stacks and multiple gate regions situated perpendicular to one another. FIGS. 1-17 represent cross section views oriented as indicated in FIG. 1

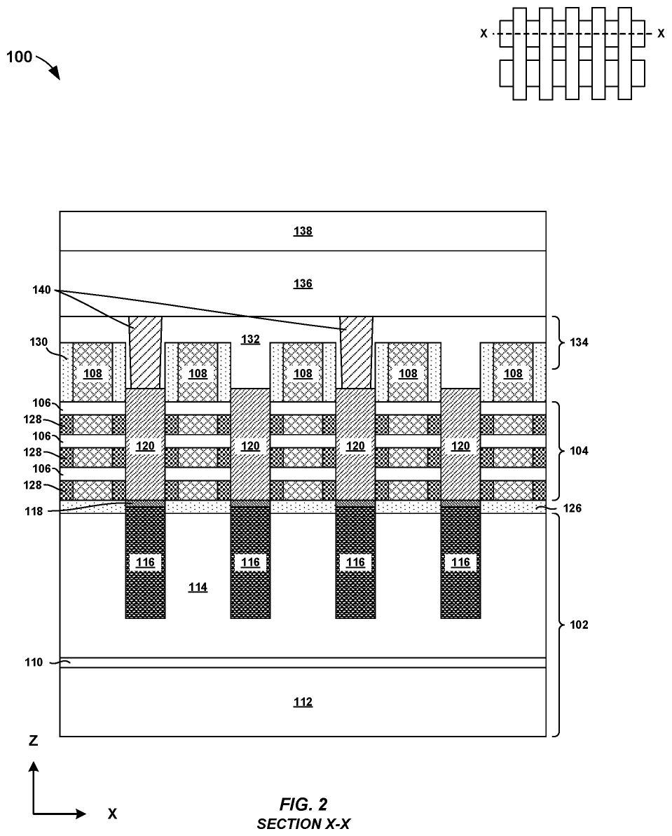

Referring now to FIG. 2, a structure 100 is shown during an intermediate step of a method of fabricating a transistor structure according to an embodiment of the invention. FIG. 2 depicts a cross-sectional view of the structure 100 shown in FIG. 1 taken along line X-X.

The structure 100 illustrated in FIG. 2 includes an array of transistors formed on a substrate 102 in accordance with known techniques. As illustrated, the array of transistors includes stacks of semiconducting layers 104. As disclosed herein, and according to embodiments of the present disclosure, the semiconducting layers further include fork sheets, nanosheets, nanowires, 2D TMD channels, other equivalent layers. Each stack of semiconducting layers 104 includes a plurality of channel regions 106 surrounded by a single gate 108. For purposes of orientation, the substrate 102 is herein referred to as being on a “backside” of the structure 100 and the array of transistors are herein referred to as being on a “frontside” of the structure 100. Further, certain features may be described herein as having a relative position with respect to the frontside or backside of the structure 100.

The substrate 102 may be a layered semiconductor such as a silicon-on-insulator or SiGe-on-insulator, where an etch stop layer 110 separates a base substrate 112 from a top semiconductor layer 114. Unlike conventional layered semiconductor substrates, the etch stop layer 110 of the substrate 102 may include any material which affects the desired etch selectivity during subsequent processing. For example, the etch stop layer 110 may be a conventional buried oxide layer, or it may be a silicon germanium layer with a specific germanium concentration. In practice, the etch stop layer 110 will function as an etch stop layer and can be composed of any material which supports that function.

In the present embodiment, both the base substrate 112 and the top semiconductor layer 114 may be any bulk substrate made from any of several known semiconductor materials such as, for example, silicon, germanium, silicon-germanium alloy, and compound (e.g. III-V and II-VI) semiconductor materials. For example, both the base substrate 112 and the top semiconductor layer 114 may be made from silicon. Additionally, both the etch stop layer 110 and the base substrate 112 are sacrificial and will not remain in the final structure. As such, thickness of the top semiconductor layer 114, and similarly the position of the etch stop layer 110, approximately denote a relative position of subsequently formed backside features, such as, backside wiring layers or a backside power delivery network.

The structure 100 further includes placeholders 116, buffer layers 118, and source/drain regions 120 generally arranged between adjacent stacks of semiconducting layers 104, as illustrated.

The placeholders 116 are formed by filling self-aligned openings in the top semiconductor layer 114 between adjacent stacks of semiconducting layers 104 with a sacrificial material according to known techniques. Specifically, after filling, the sacrificial material is recessed to create the placeholders 116 according to known techniques. In an embodiment, the sacrificial material is silicon germanium epitaxially grown from the surfaces of the top semiconductor layer 114. In another embodiment, the sacrificial material is SiC, SiOC deposited using, for example, chemical vapor deposition (CVD) or plasma enhanced CVD (PECVD) and subsequently recessed using, for example, reactive ion etching (RIE).

The buffer layers 118 are formed on top of the placeholders 116 according to known techniques. Specifically, an etch stop material is formed directly on top of the placeholders 116. In an embodiment, the etch stop material can be any silicon-based material suitable to provide needed etch stop properties during backside processing. For example, the buffer layers 118 are designed to allow the subsequent removal of the placeholders 116 selective to the source/drain regions 120.

The source/drain regions 120 are formed on top of the buffer layer 118 according to known techniques. Specifically, the source/drain regions 120 are disposed between adjacent stacks of semiconducting layers 104 in direct contact with exposed ends of the channel regions 106. More specifically, the source/drain regions 120 may be epitaxially grown from the exposed ends of the channel regions 106 according to known techniques.

The structure 100 further includes stack spacers 126, inner spacers 128, and gate spacers 130.

The stack spacers 126 are disposed directly beneath the stacks of semiconducting layers 104 separating them and the gate 108 from the substrate 102. In some embodiments, for example, the stack spacers 126 may be composed of SiN, SiBCN, SiOCN, SiOC, or any other combination of low-k materials. Like the buffer layers 118, the stack spacers 126 can provide etch selectivity during backside processing. Finally, the stack spacers 126 are optional and embodiments without the stack spacers 126 are explicitly contemplated.

As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

The inner spacers 128 are disposed between alternate channel regions 106, and laterally separate the gates 108 from the source/drain regions 120, as illustrated. The inner spacers 128 define the channel length and provide necessary electrical insulation between the gates 108 and the source/drain regions 120.

The gate spacers 130 are added to define the source/drain regions, and ultimately electrically insulate the gates 108 from subsequently formed structures, such as, for example, source/drain contact structures. The gate spacers 130 are critical for electrically insulating the gates 108 from the source/drain regions 120 or subsequently formed contact structures. In at least one embodiment, the gate spacers 130 include silicon nitride, silicon boron nitride, silicon carbon nitride, silicon boron carbon nitride, or other known equivalents.

Finally, the structure 100 further includes a dielectric layer 132 directly above and surrounding the source/drain regions 120. The dielectric layer 132 is composed of any suitable interlayer dielectric material, such as, for example, oxides such as silicon oxide (SiOₓ), nitrides such as silicon nitride (SiₓN_{y}), and/or low-K materials such as SiCOH or SiBCN. In another embodiment, is composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In yet another embodiment, a self-planarizing material such as a spin-on glass (SOG) or a spin-on low-k dielectric material such as SiLK™ can be used to form the dielectric layer 132. Using a self-planarizing dielectric material as the dielectric layer 132 can avoid the need to perform a subsequent planarizing step. After formation, top surfaces of the dielectric layer 132 are typically made flush, or substantially flush, with top surfaces of the gates 108 and the gate spacers 130 by chemical mechanical polishing techniques.

The structure 100 further includes a middle-of-line 134, a back-end-of-line 136, a carrier wafer 138.

The middle-of-line 134 includes source/drain contacts 140 and gate contacts (not shown) which may be generally referred to as middle-of-line contacts. The source/drain contacts 140 and the gate contacts are formed according to known techniques. The back-end-of-line 136 may include vias and metal lines which may be generally referred to as back-end-of-line interconnects. The vias and the metal lines are formed according to known techniques. Finally, the wafer 138 is secured to a top of the structure 100 according to an embodiment of the invention. The carrier wafer 138 is attached, or removably secured, to the back-end-of-line 136. In general, and not depicted, the carrier wafer 138 may be thicker than the other layers. Temporarily bonding the structure 100 to a thicker carrier provides improved handling and additional support for backside processing of thin wafers. After backside processing described below, the structure 100 may be de-bonded, or removed, from the carrier wafer 138 according to known techniques.

Although only a limited number of components, devices, or structures are shown, embodiments of the present invention shall not be limited by any quantity otherwise illustrated or discussed herein.

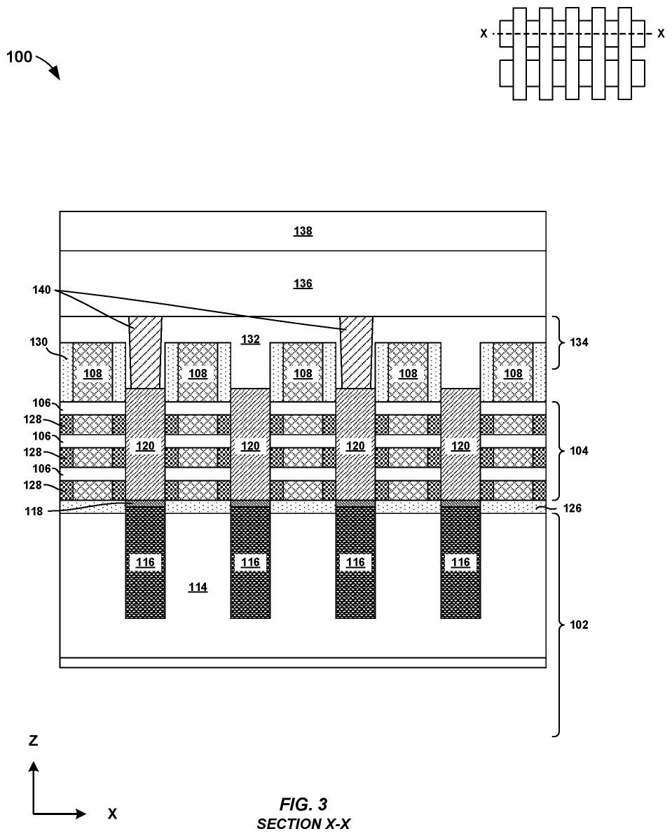

Referring now to FIG. 3, the structure 100 is shown after flipping the assembly and recessing the substrate 102 according to an embodiment of the invention. FIG. 3 depicts a cross-sectional view of the structure 100 shown in FIG. 1 taken along line X-X.

First, the structure 100 is flipped 180 degrees to prepare for backside processing. In general, backside processing includes fabrication or processing of the structure 100 opposite the active device and wiring layers. Next, the substrate 102 is recessed according to known techniques. Specifically, the base substrate 112 is recessed or completely removed to expose the etch stop layer 110, as shown. It is noted, the orientation of the cross-sectional views referenced and illustrated hereafter will remain unchanged despite the actualities of flipping of the structure 100 for purposes of fabrication. As such, all references to “upper”, “lower”, “right”, “left”, “vertical”, “horizontal”, “top”, “bottom”, and derivatives thereof shall continue to relate to the disclosed structures and methods, as oriented in the drawing figures.

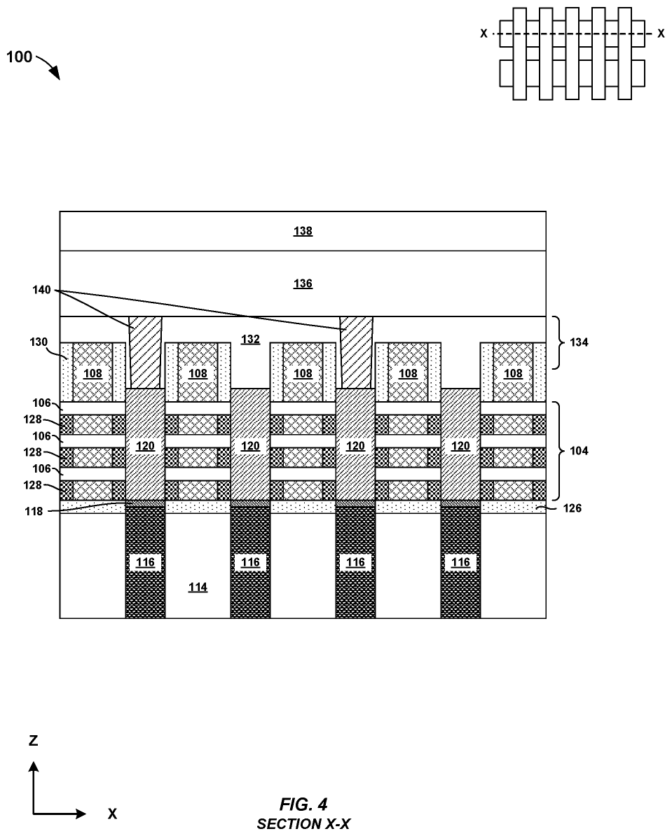

Referring now to FIG. 4, the structure 100 is shown after removing and recessing remaining portions of the substrate 102 according to an embodiment of the invention. FIG. 4 depicts a cross-sectional view of the structure 100 shown in FIG. 1 taken along line X-X.

First, the etch stop layer 110 is selectively removed and the top semiconductor layer 114 is recessed according to known techniques. Specifically, the etch stop layer 110 is removed selective to the top semiconductor layer 114. After removing the etch stop layer 110, known chemical mechanical polishing may be used to remove portions of the top semiconductor layer 114 from bottom surfaces of the structure 100. After polishing bottommost surfaces of the top semiconductor layer 114 are flush, or substantially flush, with bottommost surfaces of the placeholders 116, as illustrated. Critical to the disclosed embodiments, polishing must continue until at least bottom surfaces of the placeholders 116 are exposed, as illustrated. Doing so is necessary to enable subsequent processing according to embodiment of the present invention.

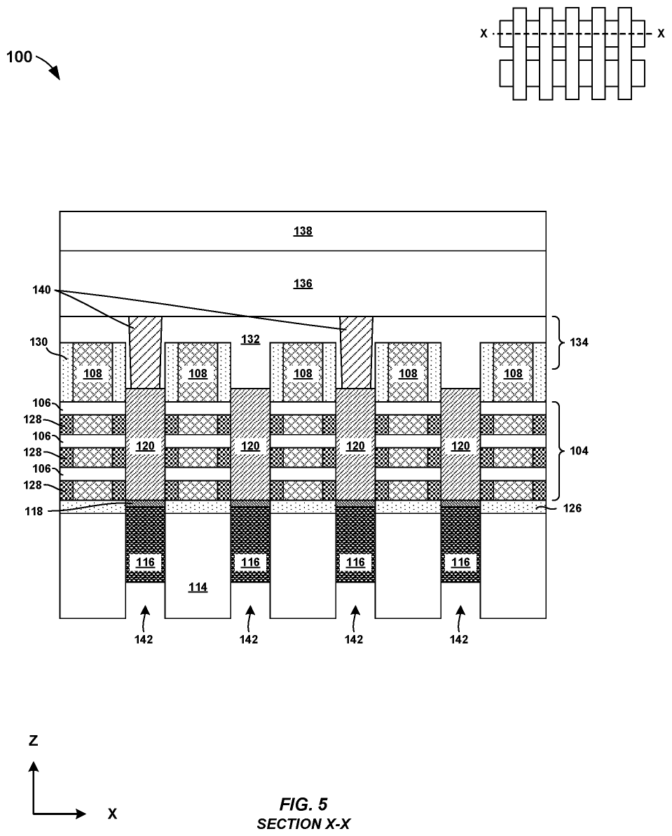

Referring now to FIG. 5, the structure 100 is shown after removing and recessing the placeholders 116 to create backside recesses 142 according to an embodiment of the invention. FIG. 4 depicts a cross-sectional view of the structure 100 shown in FIG. 1 taken along line X-X.

The placeholders 116 are recessed to form the backside recesses 142 according to known techniques. Specifically, the placeholders 116 are recessed selective to the top semiconductor layer 114, as illustrated. For example, according to embodiment disclosed herein silicon germanium of the placeholders 116 may be recessed or etched selective to the silicon based top semiconductor layer 114. The selectivity is achieved by varying the germanium according to known techniques. In all cases, the placeholders 116 should be recessed a sufficient amount to subsequently form a protecting cap. For example, too shallow a recess would result in a protective cap which is too thin and cannot provide the desired protection during subsequent etching.

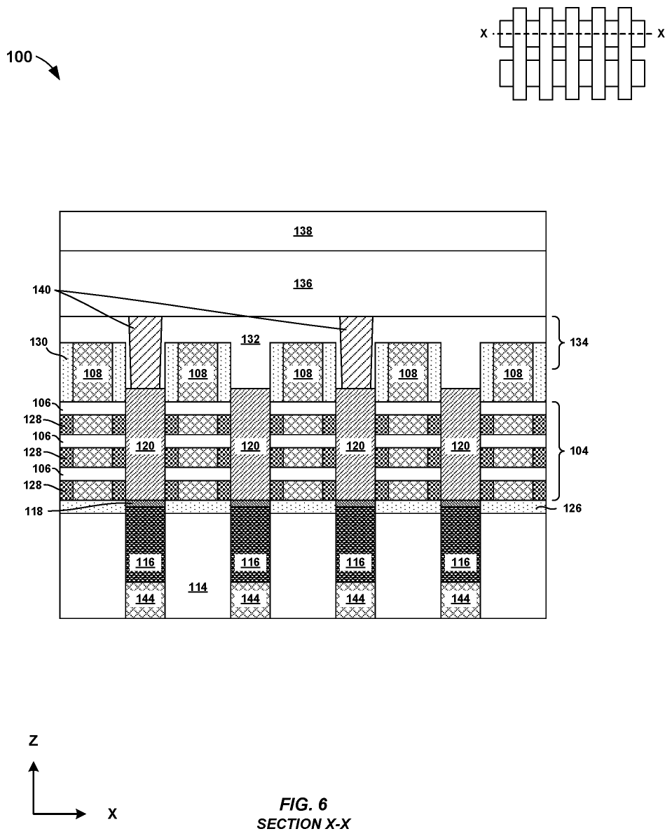

Referring now to FIG. 6, the structure 100 is shown after forming protective caps 144 within the backside recesses 142 according to an embodiment of the invention. FIG. 6 depicts a cross-sectional view of the structure 100 shown in FIG. 1 taken along line X-X.

First, the protective caps 144 are formed within the backside recesses 142 on the backside of the structure 100 according to known techniques. Specifically, a capping material is blanket deposited across exposed surfaces on the backside of the structure 100 including directly within the backside recesses 142. After deposition, excess capping material can be polished using known techniques until bottommost surfaces of the protective caps 144 are flush, or substantially flush, with bottommost surfaces of the top semiconductor layer 114, as illustrated.

In some embodiments, for example, the protective caps 144 may be composed of any dielectric which may be selectively etched relative to the surrounding materials. Typically, “harder”, more etch resistant, dielectrics are preferred, in order to avoid cap erosion during self-aligned etching. For example, suitable etch-resistance dielectrics may include SiN, AlOx, HfOx, or diamond-like carbon. According to embodiments of the present invention, the protective caps 144 provide etch selectivity and protection during subsequent backside processing. More specifically, the protective caps 144 must be made from a material which is etch selective to the top semiconductor layer 114. Stated differently, the protective caps 144 must be made from a material which will protect the placeholders 116 during subsequent etching and removal of portions of the top semiconductor layer 114, as described below.

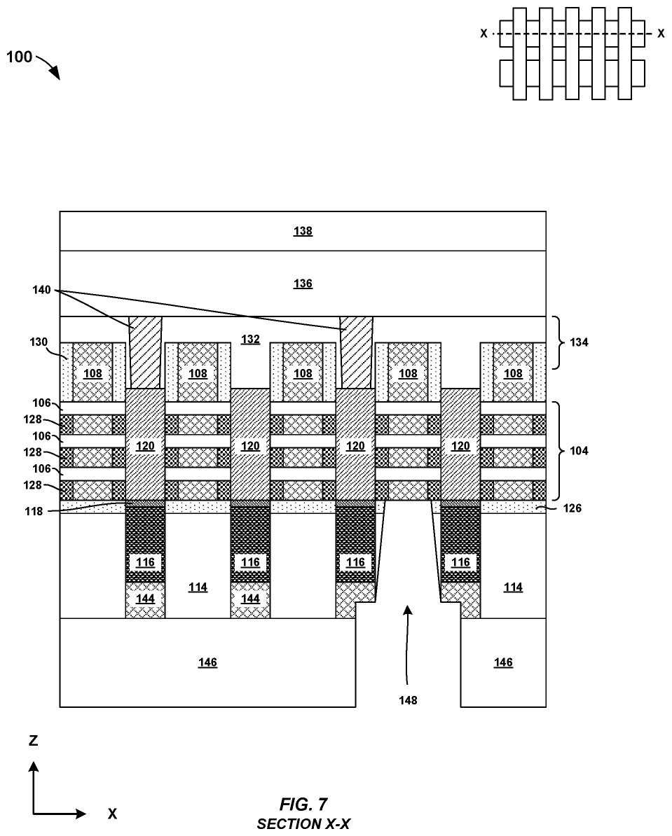

Referring now to FIG. 7, the structure 100 is shown after forming a mask 146 and forming backside access openings 148 according to an embodiment of the invention. FIG. 7 depicts a cross-sectional view of the structure 100 shown in FIG. 1 taken along line X-X.

First, the mask 146 is deposited and subsequently patterned to expose certain backside portions of the structure 100 according to known techniques. The mask 146 can be an organic planarization layer (OPL) or a layer of material that is capable of being planarized or etched by known techniques. In an embodiment, for example, the mask 146 can be an amorphous carbon layer able to withstand subsequent processing temperatures. The mask 146 can preferably have a thickness sufficient to cover existing structures. After depositing the mask 146, a dry etching technique is applied to pattern the mask 146 according to known techniques. The mask 146 is patterned to expose a region between adjacent source/drain regions 120 and directly beneath at least one of the stacks of semiconducting layers 104. In some cases, as illustrated, the pattern in the mask 146 will be oversize or larger than the desired feature size. After patterning the mask 146, portions of the structure 100 in contact with regions directly beneath at least one of the stacks of semiconducting layers 104 are exposed, as illustrated. Specific to the embodiments disclosed herein, the mask 146 is patterned selective to the protective caps 144 and the top semiconductor layer 114 (not shown).

Next, the backside access openings 148 are formed according to known techniques. Specifically, known etching techniques, such as reactive ion etching, are used to remove portions of the top semiconductor layer 114 and the stack spacers 126 selective to the inner spacers 128 and the gates 108, as illustrated. In doing so, some erosion of the protective caps 144 is anticipated. In fact, the protective caps 144 are purposefully placed to protect the placeholder 116 during etching of the backside access openings 148, as illustrated. Meanwhile, portions of the top semiconductor layer 114 remain and offer some protection to nearby sidewalls of the placeholders 116. It is noted, the backside access openings 148 will have a negative tapered profile in which a lateral width at a bottom is greater than a lateral width at the top, as illustrated.

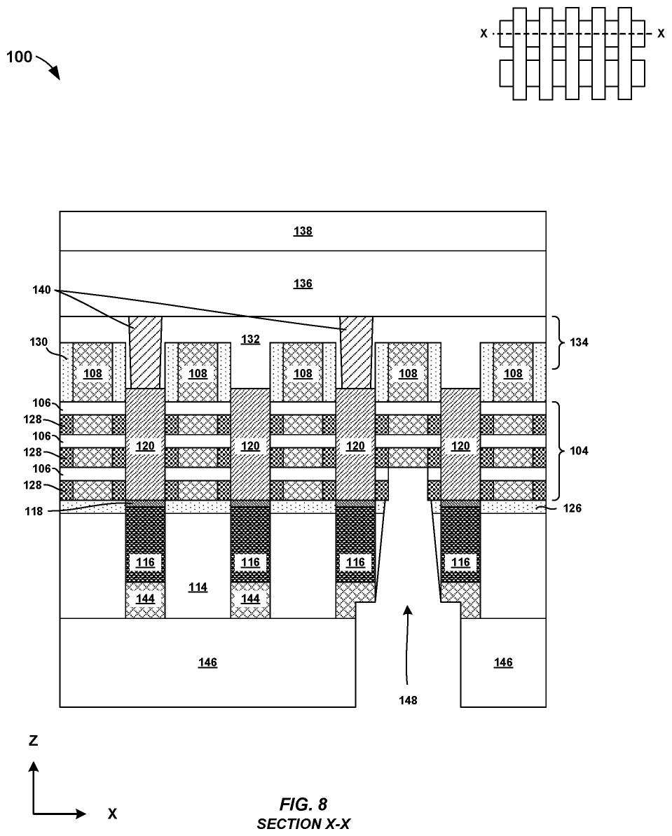

Referring now to FIG. 8, the structure 100 is shown after removing portions of the gate 108 and a bottommost channel region 106 according to an embodiment of the invention. FIG. 8 depicts a cross-sectional view of the structure 100 shown in FIG. 1 taken along line X-X.

Portions of the gate 108 and the channel regions 106 are removed according to known techniques. For example, known directional or anisotropic etching techniques are used to extend the backside access openings 148 and sequentially remove portions of the gate 108 and the channel regions 106. More specifically, the gate 108 and the channel regions 106 are etched or recessed selective to the surrounding structures, specifically the inner spacers 128. In such cases, remaining portions of the stack spacers 126 and the bottommost inner spacers 128 function as a mask or template.

Unique to the embodiments disclosed herein, the backside access opening 148 provides direct access from the backside and enables selective removal of portions of the gate 108 and/or portions of the channel regions 106. In the context of the present disclosure, and according to an embodiment, each channel region 106 illustrated in the figures, and described throughout, may include a top channel and a bottom channel. As such, the structures described and illustrated herein have a total of six channels; however, greater or fewer channel regions, and likewise channels, are explicitly contemplated. Further, one channel of the channel regions 106 is not functional, and this not present, unless surrounded by, or otherwise directly adjacent to, the gate 108. As such, removing a portion of the gate 108 directly adjacent to one of the channel regions 106 will effectively eliminate one channel from the total channel count. Therefore, selectively removing some combination of portions of the gate 108 and the channel regions 106 enable precise control of the number of channels in the exposed stack of semiconducting layers 104.

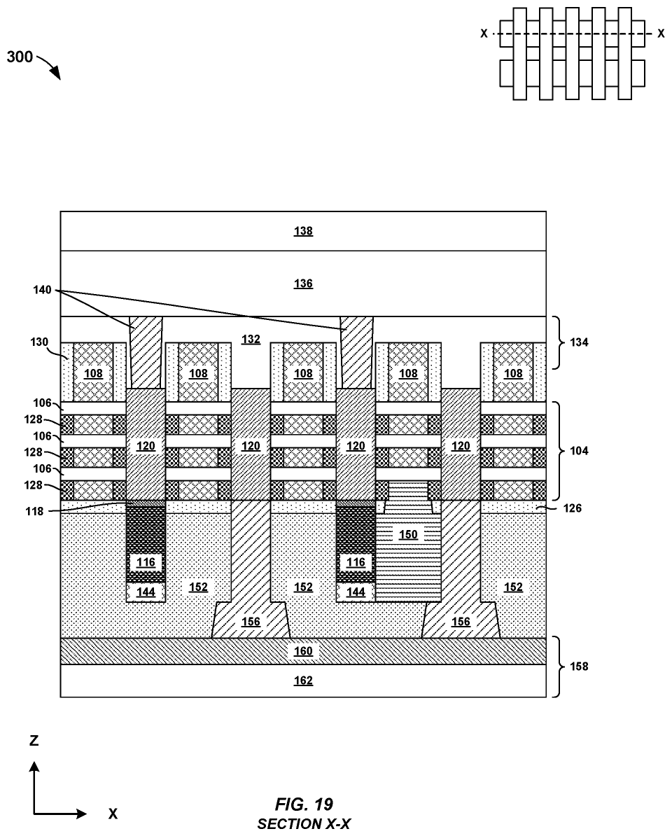

In an embodiment, for example, etching to extend the backside access openings 148 continues until a first portion of the gate 108 is removed and the bottommost channel region 106 is exposed. See FIG. 19. As indicated above, doing so will effectively eliminate the bottom channel of the bottommost channel region 106 and reduce the total channel count by one.

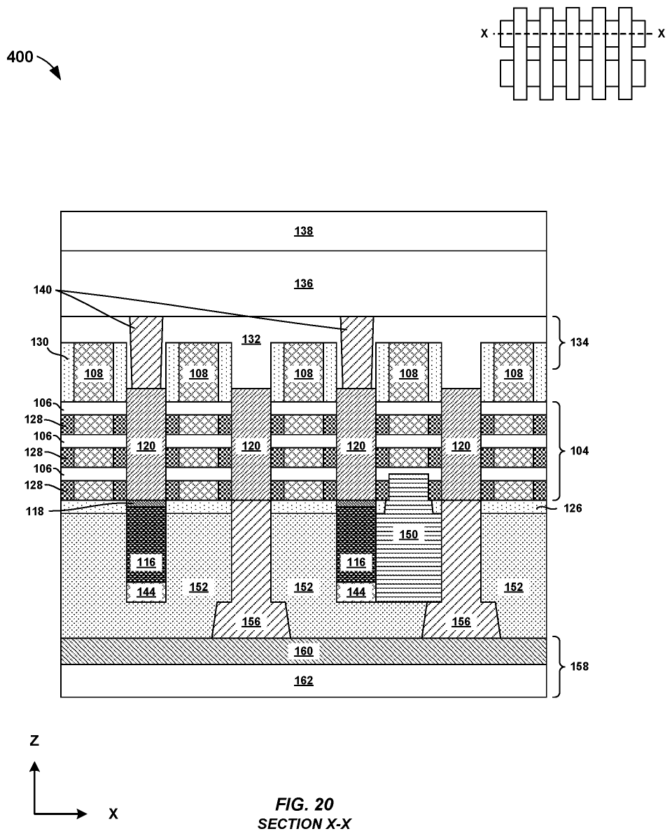

In another embodiment, for example, etching to extend the backside access openings 148 continues until the first portion of the gate 108 and at least a portion of the bottommost channel region 106 are removed. See FIG. 20. In such cases, the total channel count of the exposed stack of semiconducting layers 104 would be reduced by one.

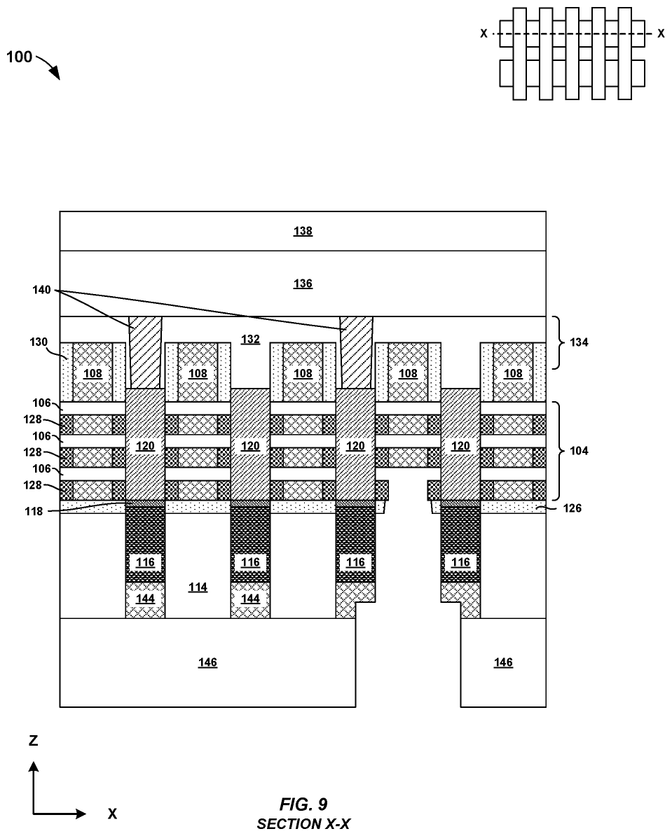

In yet another embodiment, for example, etching to extend the backside access openings 148 continues until the first portion of the gate 108 and the bottommost channel region 106 are removed, as illustrated in FIGS. 9-17. In such cases, the total channel count of the exposed stack of semiconducting layers 104 would be reduced by two.

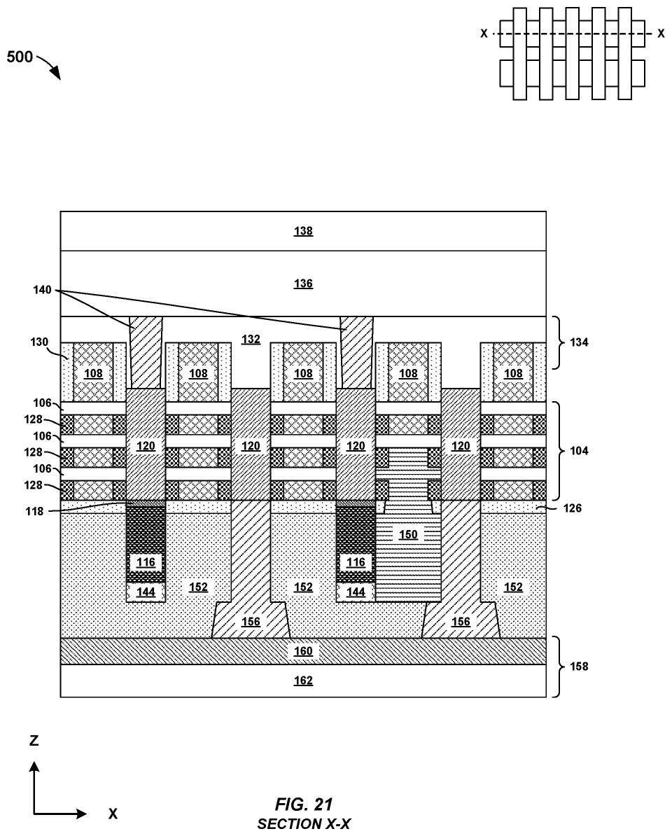

In yet another embodiment, for example, etching to extend the backside access openings 148 continues until the first portion of the gate 108, the bottommost channel region 106, and a second portion of the gate 108 are removed. See FIG. 21. In such cases, the total channel count of the exposed stack of semiconducting layers 104 would be reduced by three.

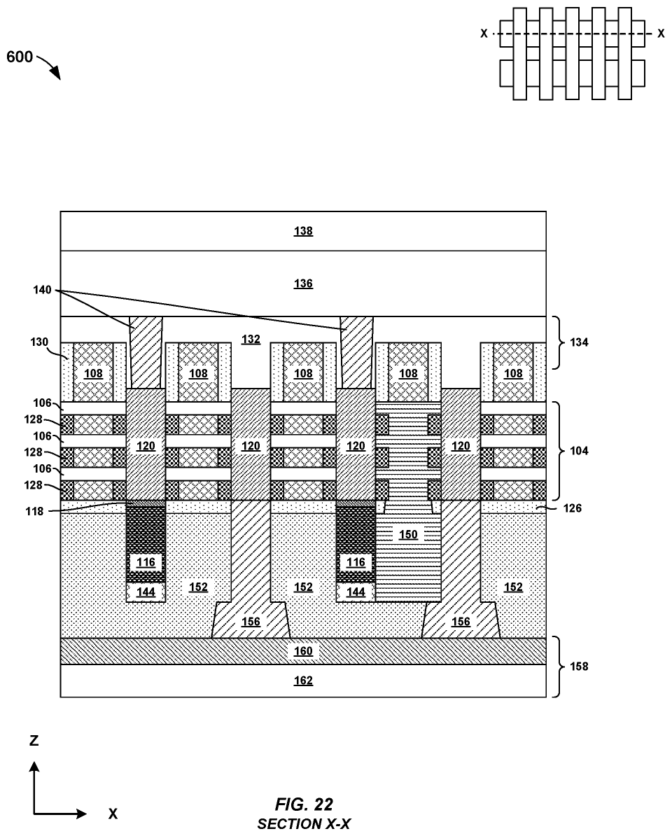

In yet another embodiment, for example, etching to extend the backside access openings 148 continues until the multiple portions of the gate 108 and all of the channel regions 106 are removed. See FIG. 22. In such cases, the total channel count of the exposed stack of semiconducting layers 104 would be reduced by six.

The ability to selectively, and strategically, remove individual channels from the exposed stack of semiconducting layers 104 enables designs which optimize power performance by uniquely tuning each stack of semiconducting layers 104 with an appropriate number of channel regions 106 to fit the needs and requirements of the design.

Referring now to FIG. 9, the structure 100 is shown after removing remaining portions of the bottommost channel region 106 according to an embodiment of the invention. FIG. 9 depicts a cross-sectional view of the structure 100 shown in FIG. 1 taken along line X-X.

The remaining portions of any channel regions 106 exposed in the extended backside access openings 148 may be optionally removed in their entirety. More specifically, a wet or isotropic etching technique maybe used to further remove any remaining portions of the channel regions 106 selective top the surrounding structures—for example, the inner spacers 128 and the source/drain regions 120. Optimally, the exposed inner spacers 128 will remain and sidewalls of the source/drain regions 120 will be exposed, as illustrated. Although further removal of remaining portions of the channel regions 106 is optional, and thus not required, doing so offers some benefit. For example, removing the remaining portions of any channel regions 106 will effectively increase the fringing field distance between portions of the gate 108 and the source/drain regions 120, and thereby reduce parasitic capacitance. Said differently, if the remaining portions of any channel regions 106 are not removed there will be a capacitance between the gate 108 and those remaining portions of any channel regions 106, and thereby causing unwanted parasitic capacitance.

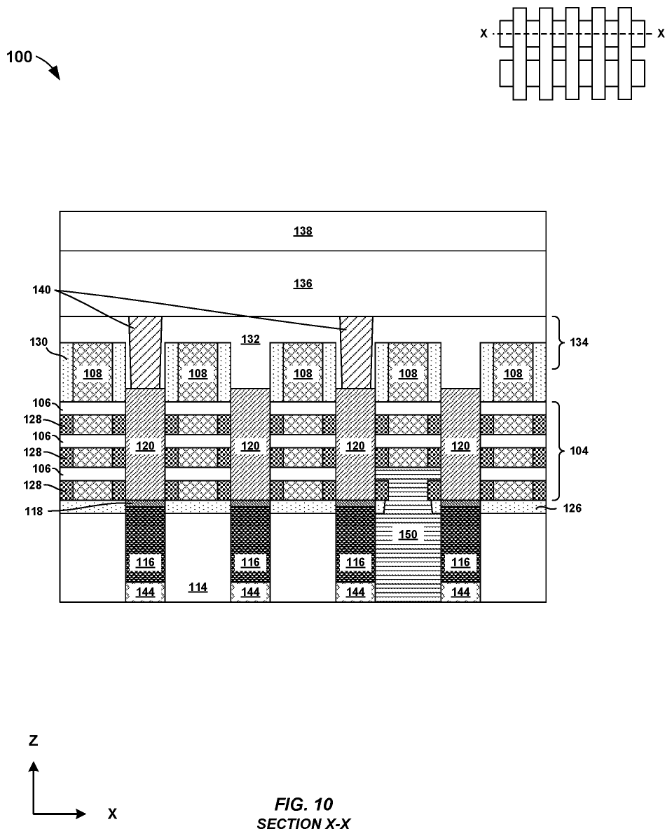

Referring now to FIG. 10, the structure 100 is shown after and forming backside channel plugs 150 according to an embodiment of the invention. FIG. 10 depicts a cross-sectional view of the structure 100 shown in FIG. 1 taken along line X-X.

First, the mask 146 is removed according to known techniques. In an embodiment, the mask 146 is removed using known techniques, such as, for example, ashing. Next, the backside access openings 148 are filled with an insulating material to form the backside channel plugs 150 according to known techniques. The backside channel plugs 150 may include any suitable low-k dielectric material, such as, for example, SiOx, SiN, SiOCN, or SiBCN. In all cases, the backside channel plugs 150 will directly contact bottommost surfaces of the gate 108, as illustrated.

In some embodiments, the backside channel plugs 150 are made from a hybrid stack of dielectrics. For example, one or more low-k dielectrics for the top portion nearest the gate 108, to minimize capacitance, and then one or more “harder” (i.e., higher-k) dielectrics for the bottommost portion to provide good etch selectivity during subsequent backside processing. In some embodiments, the backside channel plugs 150 are made from a compressive dielectric. Using a compressive dielectric would induce compressive strain in the channel regions 106 and either function to increase PFET current or decrease NFET current. In other embodiments, the backside channel plugs 150 are made from a tensile dielectric. Using a tensile dielectric would induce tensile strain in the channel regions 106 and either function to decrease PFET current or increase NFET current. In an embodiment, the backside channel plugs 150 are deposited using known deposition techniques, such as, for example, chemical vapor deposition (CVD), plasma enhanced CVD (PECVD), or atomic layer deposition (ALD).

After, excess dielectric material can be polished using known techniques until bottommost surfaces of the backside channel plugs 150 are flush, or substantially flush, with bottommost surfaces of the top semiconductor layer 114 and bottommost surfaces of the protective caps 144, as illustrated. In most cases, polishing will also recess both the top semiconductor layer 114 and the protective caps 144, as illustrated. The backside channel plugs 150 are situated between and directly contact two adjacent placeholders 116. Said differently the backside channel plugs 150 are self-aligned to protective caps 144 and the placeholder 116. In all cases, topmost surfaces of the backside channel plugs 150 is entirely above topmost surfaces of the placeholders 116. Further, top sections of the backside channel plugs 150 will have a stepped profile and wrap multiple sides of nearby inner spacers 126.

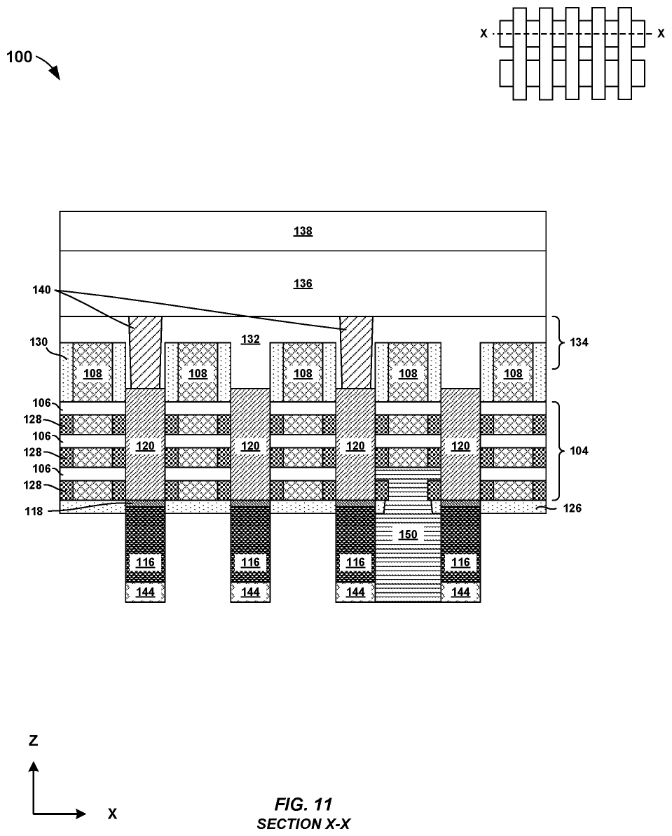

Referring now to FIG. 11, the structure 100 is shown after removing remaining portions of the substrate 102 according to an embodiment of the invention. FIG. 11 depicts a cross-sectional view of the structure 100 shown in FIG. 1 taken along line X-X.

The remaining portions of the substrate 102 are selectively removed according to known techniques. Specifically, remaining portions of the top semiconductor layer 114 are removed selective to the protective caps 144, the placeholders 116, the stack spacers 126, and the backside channel plugs 150, as illustrated. In an embodiment, the remaining portions of the top semiconductor layer 114 are removed using known wet etching techniques having appropriate etch selectively.

Although embodiments described herein disclose forming the backside channel plugs 150 prior to removing the top semiconductor layer 114 and subsequently forming a backside dielectric layer, altering the fabrication order is explicitly contemplated. For example, the backside channel plugs 150 can be formed after removing the top semiconductor layer 114 and subsequently forming a backside dielectric layer.

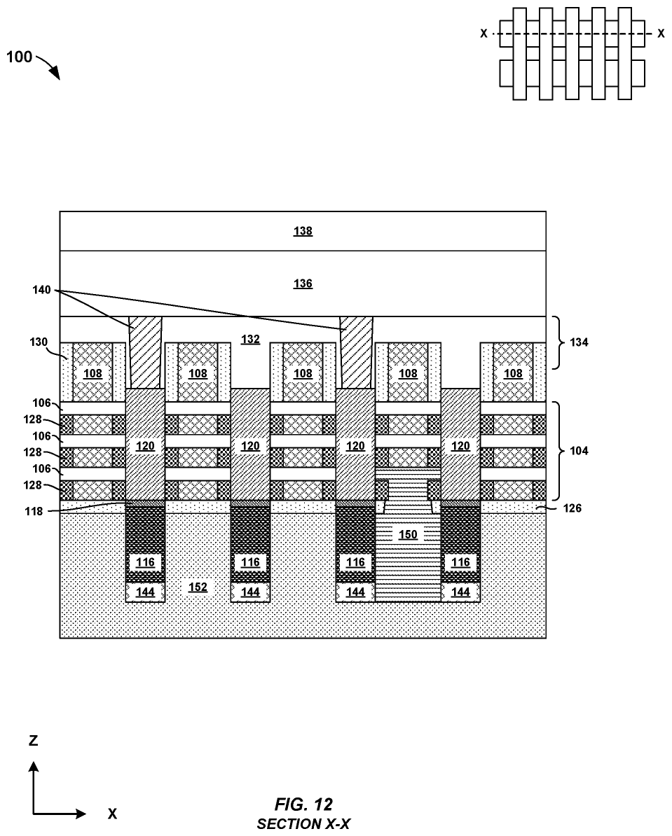

Referring now to FIG. 12, the structure 100 is shown after forming a backside dielectric layer 152 according to an embodiment of the invention. FIG. 12 depicts a cross-sectional view of the structure 100 shown in FIG. 1 taken along line X-X.

The backside dielectric layer 152 is deposited according to known techniques. Specifically, a backside dielectric material is blanket deposited across the structure 100. The backside dielectric layer 152 completely covers remaining portions of the protective caps 144, the placeholders 116, and the backside channel plugs 150, as illustrated.

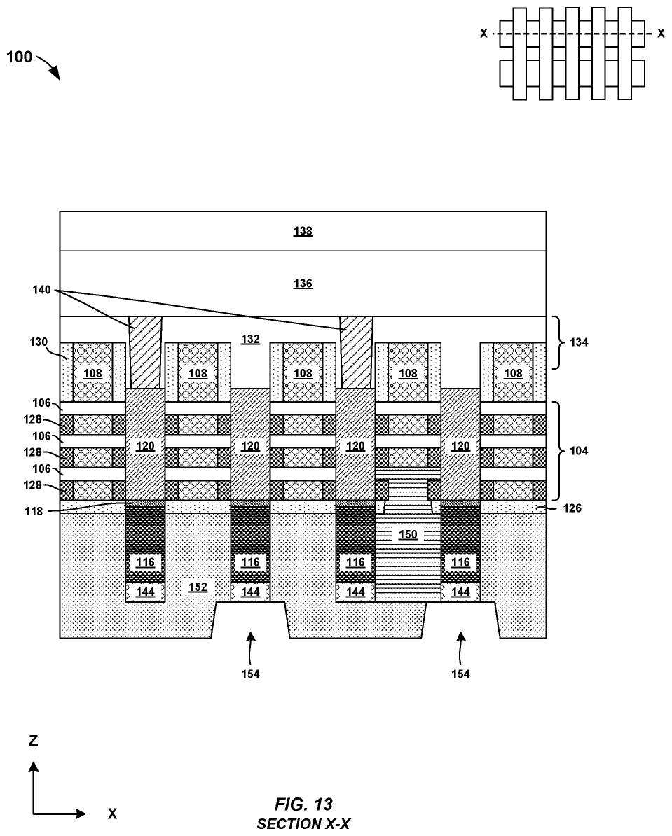

Referring now to FIG. 13, the structure 100 is shown after forming backside contact trenches 154 according to an embodiment of the invention. FIG. 13 depicts a cross-sectional view of the structure 100 shown in FIG. 1 taken along line X-X.

First, a mask (not shown) is deposited and subsequently patterned to expose certain portions of the structure 100 according to known techniques. The mask can be an organic planarization layer (OPL) or a layer of material that is capable of being planarized or etched by known techniques. In an embodiment, for example, the mask can be an amorphous carbon layer able to withstand subsequent processing temperatures. The mask can preferably have a thickness sufficient to cover existing structures. After deposition of the mask, a dry etching technique is applied to pattern the mask according to known techniques.

Next, according to an exemplary embodiment, RIE is used to transfer the mask pattern into the backside dielectric layer 152 forming the backside contact trenches 154 according to known techniques and as illustrated. According to embodiments of the present invention, the backside contact trenches 154 are generally aligned with, and expose, one or more of the protective caps 144, as illustrated.

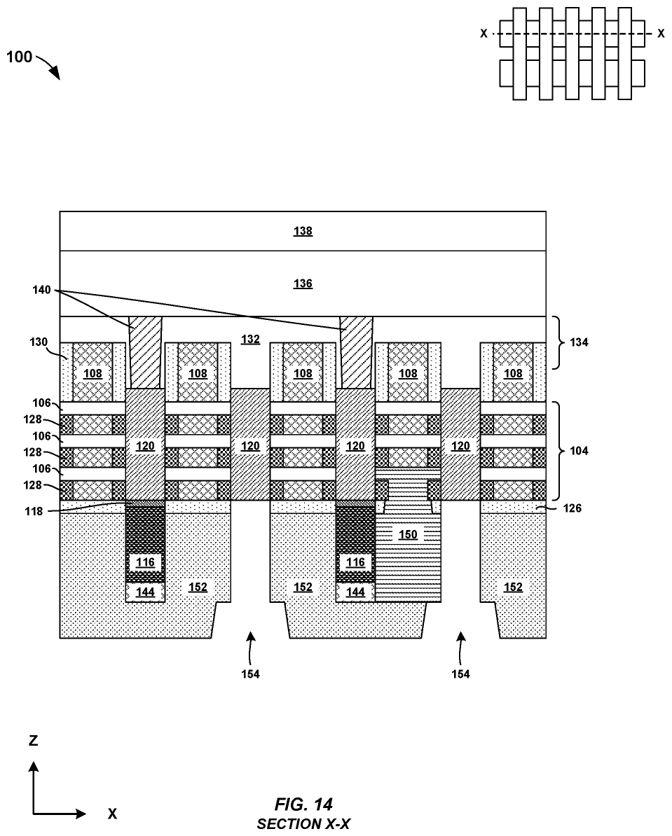

Referring now to FIG. 14, the structure 100 is shown after removing the protective caps 144 and the placeholders 116 according to an embodiment of the invention. FIG. 14 depicts a cross-sectional view of the structure 100 shown in FIG. 1 taken along line X-X.

First, the protective caps 144 exposed by the backside contact trenches 154 are selectively removed according to known techniques. Specifically, the protective caps 144 exposed by the backside contact trenches 154 are etched or removed using a RIE or wet etch selective to the backside dielectric layer 152 and the placeholders 116. Removing the exposed protective caps 144 will expose certain of the placeholders 116. Next, the certain placeholders 116 exposed by removing the protective caps 144 are selectively removed according to known techniques. Specifically, the certain placeholders 116 exposed by removing the protective caps 144 are etched or removed using a RIE or wet etch selective to the backside dielectric layer 152 and the stack spacers 126. Finally, the stack spacers 126 exposed by removing the certain placeholders 116 are subsequently removed selective to the surrounding structures according to known techniques. In doing so, certain of the source/drain regions 120 are exposed from the backside, as illustrated. Unique to the embodiments disclosed herein, the protective caps 144, the placeholders 116 and the stack spacers 126 are all removed selective to the backside channel plugs 150, as illustrated. Said differently, the backside channel plugs 150 substantially remain unchanged; however, some etching or erosion of the backside channel plugs 150 is acceptable, and perhaps expected with certain etching less-selective techniques.

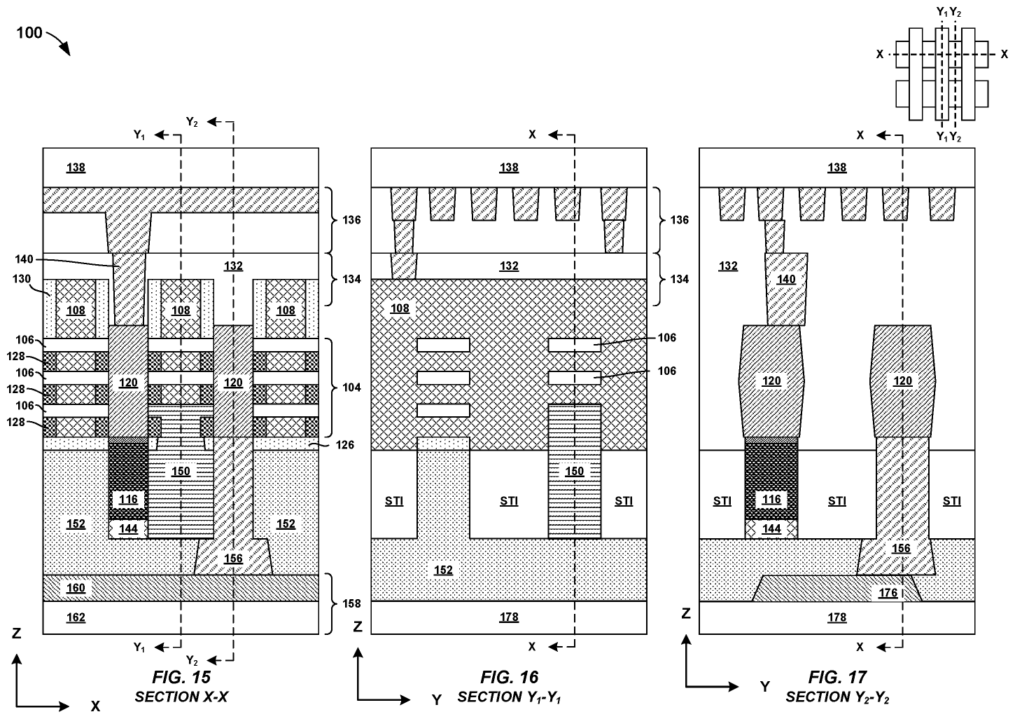

Referring now to FIGS. 15, 16, and 17, the structure 100 is shown after forming backside contact structures 156 and backside wiring layers 158 according to an embodiment of the invention. FIG. 15 depicts a cross-sectional view of the structure 100 shown in FIGS. 16 and 17 taken along line X-X, FIG. 16 depicts a cross-sectional view of the structure 100 shown in FIG. 15 taken along line Y₁-Y₁, and FIG. 17 depicts a cross-sectional view of the structure 100 shown in FIG. 15 taken along line Y₂-Y₂.

The backside contact trenches 154 are then filled with a conductive material to form the backside contact structures 156 according to known techniques. The backside contact structures 156 may include any suitable conductive material, such as, for example, copper, ruthenium, aluminum, tungsten, cobalt, or alloys thereof. In some embodiments, a metal silicide is formed at the bottom of the backside contact trenches 154 prior to filling them with the conductive material. After, excess conductive material can be polished using known techniques until bottommost surfaces of the backside contact structures 156 are flush, or substantially flush, with bottommost surfaces of the backside dielectric layer 152, as illustrated. It is noted, the backside contact structures 156 may include, for example, backside source/drain contacts, as illustrated, as well as backside gate contacts.

After forming the backside contact structures 156, the backside wiring layers 158 are subsequently formed according to known techniques. The backside wiring layers 158 typically include at least backside power rails 160 and a backside power delivery network 162.

According to the embodiment illustrated in FIGS. 15, 16, and 17, the transistor structures represented by the structure 100 have some distinctive notable features. For instance, the structure 100 includes the backside channel plugs 150 situated between and directly contacting one of the placeholders 116 and one of the backside contact structures 156, as best illustrated in FIG. 15. As such, the backside channel plugs 150 are self-aligned to, and directly contact, the placeholder 116 and the backside contact structures 156, as best illustrated in FIG. 15. The backside channel plugs 150 are further self-aligned to, and directly contact, STI regions, as best illustrated in FIG. 16. The structure 100 further includes one stack of semiconducting layers 104 with three channel regions 106 adjacent to another stack of semiconducting layers 104 having only two channel regions 106. Specifically, in the present embodiment, etching to extend the backside access openings 148 (see FIG. 8) continues until a first portion of the gate 108 and at least one channel region 106 are removed. More specifically, a first portion of the gate 108 and the bottommost channel region 106 are removed, as illustrated. In such cases, the total channel count of the exposed stack of semiconducting layers 104 would be reduced by two.

It is further reiterated, the transistor structures represented by the structure 100 are an example and representative of embodiment of the present disclosure. As such, structures with a greater or fewer number channel regions 106 is explicitly contemplated herein. Removing individual channel regions from the backside according to embodiments disclosed herein, provides a novel solution for conserving power and optimizing performance to suit different design constraints without the need for advance scaling technologies or scaling solutions.

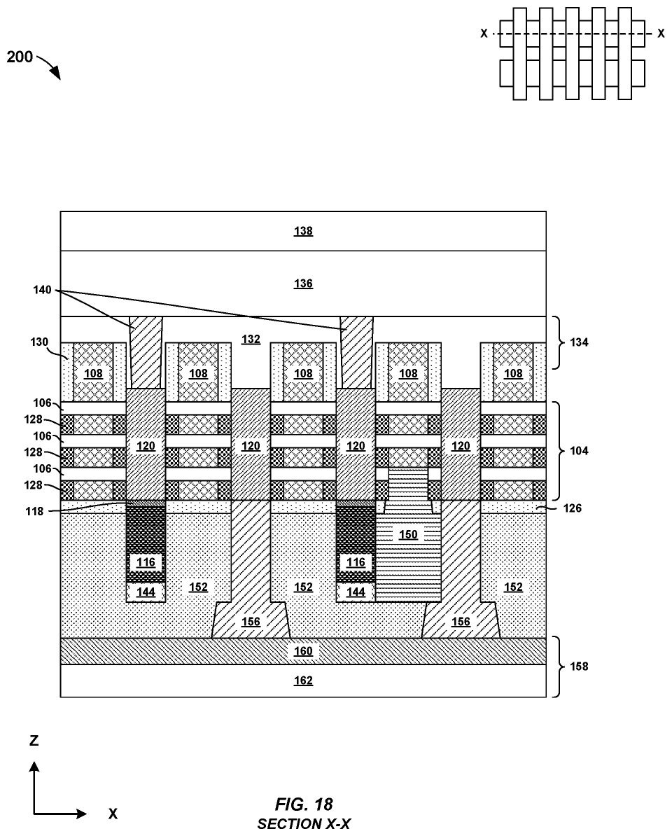

Referring now to FIG. 18, a structure 200 is shown during an intermediate step of a method of fabricating a transistor structure according to an alternative embodiment of the invention. FIG. 18 depicts a cross-sectional view similar to cross-sectional views of the structure 100 provided above.

The structure 200 is substantially similar to the structure 100 described above and is produced by a similar process flow described above with respect to the structure 100 except for the following differences. The structure 200 of FIG. 18 represents the resulting structure when the optional removal of remaining portions of any channel regions (106) exposed in the extended backside access openings 148 is skipped or omitted. As such, some end portions of the bottommost channel region (106) remain, as illustrated. Despite the end portions of the bottommost channel region (106) remaining, the bottommost channel region (106) is no longer operational and therefore no longer remains. Said differently, unlike the structure 100 in which the bottommost channel region (106) was removed in its entirety, only a center portion of the bottommost channel region (106) in the structure 200 was removed and end portions remain. Despite the undesirable parasitic capacitance caused by the remaining end portions, as described above, this provides at least another example of how the process described above with respect to the structure 100 can be tailored to suit designer's needs.

Referring now to FIG. 19, a structure 300 is shown during an intermediate step of a method of fabricating a transistor structure according to an alternative embodiment of the invention. FIG. 19 depicts a cross-sectional view similar to cross-sectional views of the structure 100 provided above.

The structure 300 is substantially similar to the structure 100 described above and is produced by a similar process flow described above with respect to the structure 100 except for the following differences. The structure 300 of FIG. 19 represents the resulting structure when the etching technique used to remove portions of the gate 108 and the channel regions 106 (see FIG. 8) is adjusted or further tailored to suit designer's needs. Specifically, in the present embodiment, etching to extend the backside access openings 148 (see FIG. 8) stops prior to etching through any portions of the bottommost channel region 106, as illustrated. In such cases, only a first portion of the gate 108 is removed, thereby effectively eliminating the bottom channel of the bottommost channel region 106.

Referring now to FIG. 20, a structure 400 is shown during an intermediate step of a method of fabricating a transistor structure according to an alternative embodiment of the invention. FIG. 20 depicts a cross-sectional view similar to cross-sectional views of the structure 100 provided above.

The structure 400 is substantially similar to the structure 100 described above and is produced by a similar process flow described above with respect to the structure 100 except for the following differences. The structure 400 of FIG. 20 represents the resulting structure when the etching technique used to remove portions of the gate 108 and the channel regions 106 (see FIG. 8) is adjusted or further tailored to suit designer's needs. Specifically, in the present embodiment, etching to extend the backside access openings 148 (see FIG. 8) stops prior to etching through an entire thickness of the bottommost channel region 106, as illustrated. In doing so, only a portion of the bottommost channel region 106 is removed during etching to extend the backside access openings 148. As such, only the bottom channel of the bottommost channel region 106 is removed, and the total channel count of the exposed stack of semiconducting layers 104 would be reduced by one.

Referring now to FIG. 21, a structure 500 is shown during an intermediate step of a method of fabricating a transistor structure according to an alternative embodiment of the invention. FIG. 21 depicts a cross-sectional view similar to cross-sectional views of the structure 100 provided above.

The structure 500 is substantially similar to the structure 100 described above and is produced by a similar process flow described above with respect to the structure 100 except for the following differences. The structure 500 of FIG. 21 represents the resulting structure when the etching technique used to remove portions of the gate 108 and the channel regions 106 (see FIG. 8) is adjusted or further tailored to suit designer's needs. Specifically, in the present embodiment, etching to extend the backside access openings 148 (see FIG. 8) continues until multiple portions of the gate 108 and at least one channel region 106 is removed. More specifically, a first portion of the gate 108, the bottommost channel region 106, and first portion of the gate 108 are removed, as illustrated. In such cases, the total channel count of the exposed stack of semiconducting layers 104 would be reduced by three.

Referring now to FIG. 22, a structure 600 is shown during an intermediate step of a method of fabricating a transistor structure according to an alternative embodiment of the invention. FIG. 22 depicts a cross-sectional view similar to cross-sectional views of the structure 100 provided above.

The structure 600 is substantially similar to the structure 100 described above and is produced by a similar process flow described above with respect to the structure 100 except for the following differences. The structure 600 of FIG. 22 represents the resulting structure when the etching technique used to remove portions of the gate 108 and the channel regions 106 (see FIG. 8) is adjusted or further tailored to suit designer's needs. Specifically, in the present embodiment, etching to extend the backside access openings 148 (see FIG. 8) continues until multiple portions of the gate 108 and all of the channel regions 106 are removed. In such cases, the total channel count of the exposed stack of semiconducting layers 104 would be reduced by six.

Finally, embodiments involving permutations of the embodiments illustrated in FIGS. 15-22 are explicitly contemplated.

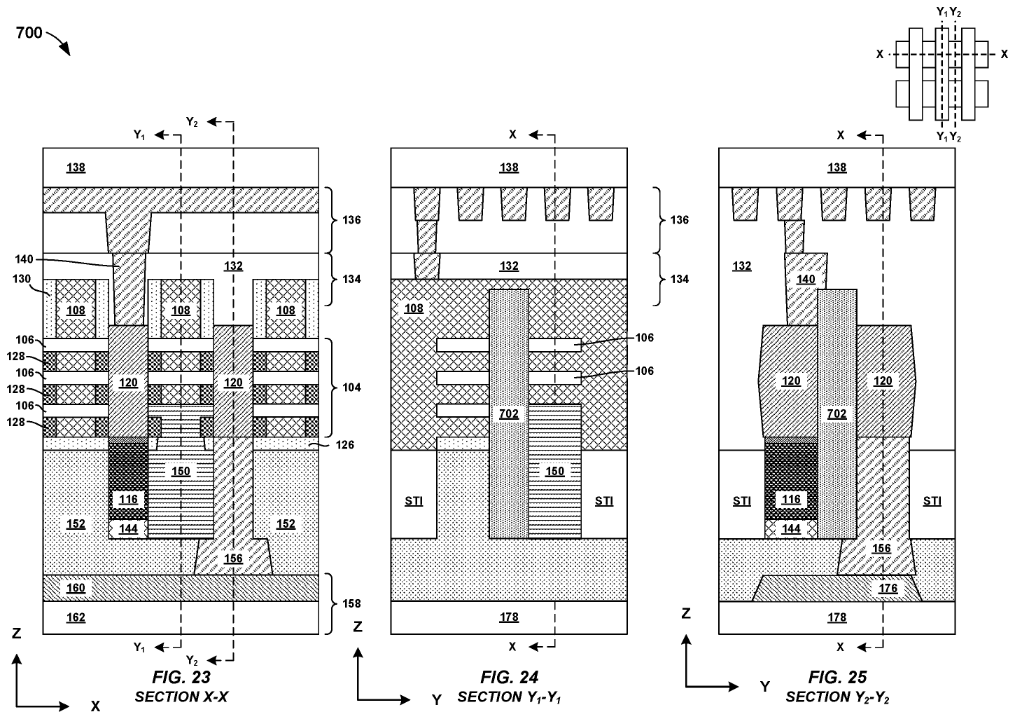

Referring now to FIGS. 23, 24, and 25, a structure 700 is shown during an intermediate step of a method of fabricating a nanosheet transistor structure according to an alternative embodiment of the invention. FIG. 23 depicts a cross-sectional view of the structure 100 shown in FIGS. 24 and 25 taken along line X-X, FIG. 24 depicts a cross-sectional view of the structure 100 shown in FIG. 23 taken along line Y₁-Y₁, and FIG. 25 depicts a cross-sectional view of the structure 100 shown in FIG. 23 taken along line Y₂-Y₂.

The structure 700 is substantially similar to the structure 100 described above and is produced by a similar process flow described above with respect to the structure 100 except for the following differences. The structure 700 of FIGS. 23-25 represents a resulting structure further including a dielectric bar 702, or dielectric wall, between adjacent stacks of semiconducting layers 104. Such structures are commonly referred to as a tri-gate forked structure or a fork sheet structure. The dielectric bar 702 physically isolates the adjacent stacks of semiconducting layers 104 from one another, allowing tighter spacing which facilitates superior area and performance scalability compared to traditional devices. The structure 700 has similar distinctive and notable features as described above with respect to the structure 100 described above.

With continued reference to FIGS. 15-25, and according to an embodiment, the structure 100 includes a first stack of semiconducting layers, a second stack of semiconducting layers, where the first stack of semiconducting layers has at least one fewer layer than the second stack of semiconducting layers, and a backside channel plug directly beneath the first stack of semiconducting layers.

With continued reference to FIG. 15-25, and according to an embodiment, a width of the backside channel plug is substantially equal to a width of the first stack of semiconducting layers.

With continued reference to FIG. 15-25, and according to an embodiment, the backside channel plug comprises a top portion, a middle portion, and a bottom portion, where a width of the middle portion is less than a width of either the top portion or the bottom portion.

With continued reference to FIG. 15-25, and according to an embodiment, the backside channel plug is self-aligned to a backside contact structure and a placeholder.

With continued reference to FIG. 15-25, and according to an embodiment, the structure further includes a backside contact structure, a placeholder adjacent to the backside contact structure and directly beneath a source/drain region, where the backside channel plug is arranged between and separates the backside contact structure from the placeholder.

With continued reference to FIG. 15-25, and according to an embodiment, the backside channel plug comprises a compressive dielectric material, a tensile dielectric material, or some combination thereof.

With continued reference to FIG. 15-25, and according to an embodiment, the backside channel plug comprises two or more dielectric materials.

With continued reference to FIG. 15-25, and according to an embodiment, the structure 100 includes a first stack of semiconducting layers, a second stack of semiconducting layers, where a top surface of a top layer of the first stack of semiconducting layers is substantially flush with a top surface of a top layer of the second stack of semiconducting layers, and where a bottom surface of a bottom layer of the first stack of semiconducting layers is above a bottom surface of a bottom layer of the second stack of semiconducting layers, and a backside channel plug below the first stack of semiconducting layers.

With continued reference to FIG. 15-25, and according to an embodiment, the structure 100 includes a first stack of semiconducting layers including a first gate surrounding at least one layer of the first stack of semiconducting layers, a second stack of semiconducting layers including a second gate surrounding at least one layer of the second stack of semiconducting layers, where a topmost surface of the first gate is substantially flush with a topmost surface of the second gate, and a bottommost surface of the first gate is above a bottommost surface of the second gate, and a backside channel plug below and in direct contact with the bottommost surface of the second gate.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
a first stack of semiconducting layers;
a second stack of semiconducting layers, wherein the first stack of semiconducting layers has at least one fewer layer than the second stack of semiconducting layers; and
a backside channel plug directly beneath the first stack of semiconducting layers.

2. The semiconductor structure according to claim 1, wherein a width of the backside channel plug is substantially equal to a width of the first stack of semiconducting layers.

3. The semiconductor structure according to claim 1, wherein the backside channel plug comprises a top portion, a middle portion, and a bottom portion, wherein a width of the middle portion is less than a width of either the top portion or the bottom portion.

4. The semiconductor structure according to claim 1, wherein the backside channel plug is self-aligned to a backside contact structure and a placeholder.

5. The semiconductor structure according to claim 1, further comprising:
a backside contact structure;
a placeholder adjacent to the backside contact structure and directly beneath a source/drain region; and
wherein the backside channel plug is arranged between and separates the backside contact structure from the placeholder.

6. The semiconductor structure according to claim 1, wherein the backside channel plug comprises a compressive dielectric material, a tensile dielectric material, or some combination thereof.

7. The semiconductor structure according to claim 1, wherein the backside channel plug comprises two or more dielectric materials.

8. A semiconductor structure comprising:
a first stack of semiconducting layers;
a second stack of semiconducting layers, wherein a top surface of a top layer of the first stack of semiconducting layers is substantially flush with a top surface of a top layer of the second stack of semiconducting layers, and wherein a bottom surface of a bottom layer of the first stack of semiconducting layers is above a bottom surface of a bottom layer of the second stack of semiconducting layers; and
a backside channel plug below the first stack of semiconducting layers.

9. The semiconductor structure according to claim 8, wherein a width of the backside channel plug is substantially equal to a width of the first stack of semiconducting layers.

10. The semiconductor structure according to claim 8, wherein the backside channel plug comprises a top portion, a middle portion, and a bottom portion, wherein a width of the middle portion is less than a width of either the top portion or the bottom portion.

11. The semiconductor structure according to claim 8, wherein the backside channel plug is self-aligned to a backside contact structure and a placeholder.

12. The semiconductor structure according to claim 8, further comprising:
a backside contact structure;
a placeholder adjacent to the backside contact structure and directly beneath a source/drain region; and
wherein the backside channel plug is arranged between and separates the backside contact structure from the placeholder.

13. The semiconductor structure according to claim 8, wherein the backside channel plug comprises a compressive dielectric material, a tensile dielectric material, or some combination thereof.

14. The semiconductor structure according to claim 8, wherein the backside channel plug comprises two or more dielectric materials.

15. A semiconductor structure comprising:
a first stack of semiconducting layers including a first gate surrounding at least one layer of the first stack of semiconducting layers;
a second stack of semiconducting layers including a second gate surrounding at least one layer of the second stack of semiconducting layers, wherein a topmost surface of the first gate is substantially flush with a topmost surface of the second gate, and a bottommost surface of the first gate is above a bottommost surface of the second gate; and
a backside channel plug below and in direct contact with the bottommost surface of the second gate.

16. The semiconductor structure according to claim 15, wherein a first width of the backside channel plug is substantially equal to a width of the first stack of semiconducting layers, and a second width of the backside channel plug is substantially equal to a width of the first gate.

17. The semiconductor structure according to claim 15, wherein the backside channel plug comprises a top portion, a middle portion, and a bottom portion, wherein a width of the middle portion is less than a width of either the top portion or the bottom portion.

18. The semiconductor structure according to claim 15, wherein the backside channel plug is self-aligned to a backside contact structure and a placeholder.

19. The semiconductor structure according to claim 15, wherein the backside channel plug comprises a compressive dielectric material, a tensile dielectric material, or some combination thereof.

20. The semiconductor structure according to claim 15, wherein the backside channel plug comprises two or more dielectric materials.
